(19) United States
(12) Patent Application Publication
(10) Pub. No.: US 2025/0132096 A1
(43) Pub. Date: Apr. 24, 2025

(54) MULTILAYER CERAMIC CAPACITOR AND MULTILAYER CERAMIC CAPACITOR MOUNTING STRUCTURE

(71) Applicant: KYOCERA Corporation, Kyoto-shi, Kyoto (JP)

(72) Inventors: Tomohiro YANO, Kirishima-shi (JP); Koshiro SUGIMOTO, Kirishima-shi (JP)

(73) Assignee: KYOCERA Corporation, Kyoto-shi, Kyoto (JP)

(21) Appl. No.: 18/836,227

(22) PCT Filed: Feb. 9, 2023
(86) PCT No.: PCT/JP2023/004365

§ 371 Date: Aug. 6, 2024

(30) Foreign Application Priority Data
Feb. 15, 2022 (JP) 2022-021616

(51) Int. Cl. H01G 4/30; H01G 4/012; H05K 1/18

(52) U.S. Cl. CPC H01G 4/30; H01G 4/012; H05K 1/181; H05K 2201/10015

(57) ABSTRACT

A multilayer ceramic capacitor includes a body including first and second internal electrodes alternately stacked in a first direction with a dielectric layer between them and first and second electrodes alternately stacked in the first direction with the dielectric layer between them, first and second external electrodes on the first surface, and third and fourth external electrodes on the second surface. The first internal electrode includes a first portion including a first capacitance portion and first and second extensions. The second internal electrode includes a second portion including a second capacitance portion and third and fourth extensions. The first electrode includes first and second inspection electrodes. The second electrode includes third and fourth inspection electrodes. The first and second extensions are connected to the first and third external electrodes. The third and fourth extensions are connected to the second and fourth external electrodes.

### TECHNICAL FIELD

The present disclosure relates to a multilayer ceramic capacitor and a multilayer ceramic capacitor mounting structure.

### BACKGROUND OF INVENTION

Known multilayer ceramic capacitors are described in, for example, Patent Literatures 1 and 2.

### CITATION LIST

### Patent Literature

Patent Literature 1: Japanese Unexamined Patent Application Publication No. 2020-167368
Patent Literature 2: Japanese Unexamined Patent Application Publication No. 2004-140183

### SUMMARY

In an aspect of the present disclosure, a multilayer ceramic capacitor includes a body, a first external electrode and a second external electrode, and a third external electrode and a fourth external electrode. The body is a substantially rectangular prism. The body includes a first internal electrode and a second internal electrode alternately stacked in a first direction with a dielectric layer between the first internal electrode and the second internal electrode. The body includes a first electrode and a second electrode alternately stacked in the first direction with the dielectric layer between the first electrode and the second electrode. The body includes a first side surface and a second side surface opposite to each other in the first direction, a first surface and a second surface opposite to each other, and a first end face and a second end face opposite to each other. The first external electrode and a second external electrode are on the first surface. The third external electrode and a fourth external electrode are on the second surface. The first internal electrode includes a first portion including a first capacitance portion, a first extension, and a second extension. The second internal electrode includes a second portion including a second capacitance portion, a third extension, and a fourth extension. The first electrode includes a first inspection electrode and a second inspection electrode. The second electrode includes a third inspection electrode and a fourth inspection electrode. The first extension extends to the first surface and is connected to the first external electrode. The second extension extends to the second surface and is connected to the third external electrode. The third extension extends to the first surface and is connected to the second external electrode. The fourth extension extends to the second surface and is connected to the fourth external electrode.

In another aspect of the present disclosure, a multilayer ceramic capacitor mounting structure includes the above multilayer ceramic capacitor, and a substrate including a mounting surface. The multilayer ceramic capacitor is mounted on the mounting surface with the first side surface perpendicular to the mounting surface.

### BRIEF DESCRIPTION OF THE DRAWINGS

The objects, features, and advantages of the present disclosure will be more apparent from the following detailed description and the drawings.

FIG. 1 is a perspective view of a multilayer ceramic capacitor according to an embodiment of the present disclosure.

FIG. 2 is an exploded perspective view of the multilayer ceramic capacitor according to the embodiment of the present disclosure.

FIG. 3A is a cross-sectional view taken along section line IIIA-IIIA in FIG. 1.

FIG. 3B is a cross-sectional view taken along section line IIIB-IIIB in FIG. 1.

FIG. 4A is a side view of electrode patterns on three multilayer ceramic capacitors.

FIG. 4B is an enlarged view of a part IVB in FIG. 4A.

FIG. 5A is a cross-sectional view taken along section line A-A in FIG. 4A.

FIG. 5B is a cross-sectional view taken along section line B-B in FIG. 4A.

FIG. 5C is a cross-sectional view taken along section line C-C in FIG. 4A.

FIG. 6A is a cross-sectional view of the multilayer ceramic capacitor after firing as viewed from a perpendicular plane (first direction X) different from adjacent end faces taken along section line A-A in FIG. 4A.

FIG. 6B is a cross-sectional view of the multilayer ceramic capacitor after firing as viewed from the perpendicular plane (first direction X) different from adjacent end faces taken along section line B-B in FIG. 4A.

FIG. 6C is a cross-sectional view of the multilayer ceramic capacitor after firing as viewed from the perpendicular plane (first direction X) different from adjacent end faces taken along section line C-C in FIG. 4A.

FIG. 7 is a side view of a mounting structure according to one embodiment of the present disclosure.

FIG. 8A is a diagram of an electrode pattern on a multilayer ceramic capacitor.

FIG. 8B is a diagram of an electrode pattern on the multilayer ceramic capacitor.

FIG. 8C is a diagram of an electrode pattern on the multilayer ceramic capacitor.

FIG. 8D is a diagram of an electrode pattern on the multilayer ceramic capacitor.

FIG. 9A is a diagram of an electrode pattern on a multilayer ceramic capacitor according to another embodiment.

FIG. 9B is a diagram of an electrode pattern on the multilayer ceramic capacitor according to another embodiment.

FIG. 9C is a diagram of an electrode pattern on the multilayer ceramic capacitor according to another embodiment.

FIG. 9D is a diagram of an electrode pattern on the multilayer ceramic capacitor according to another embodiment.

FIG. 9E is a diagram of an electrode pattern on the multilayer ceramic capacitor according to another embodiment.

FIG. 10A is a diagram of an electrode pattern on a multilayer ceramic capacitor according to still another embodiment.

FIG. 10B is a diagram of an electrode pattern on the multilayer ceramic capacitor according to another embodiment.

FIG. 10C is a diagram of an electrode pattern on the multilayer ceramic capacitor according to another embodiment.

FIG. 10D is a diagram of an electrode pattern on the multilayer ceramic capacitor according to another embodiment.

FIG. 10E is a diagram of an electrode pattern on the multilayer ceramic capacitor according to another embodiment.

FIG. 11 is a perspective view of a multilayer ceramic capacitor according to another embodiment of the present disclosure.

FIG. 12 is an exploded perspective view of the multilayer ceramic capacitor according to another embodiment of the present disclosure.

FIG. 13 is a cross-sectional view taken along section line XIII-XIII in FIG. 11.

FIG. 14A is a diagram of an electrode pattern on the multilayer ceramic capacitor according to the embodiment in FIGS. 12 and 13.

FIG. 14B is a diagram of the electrode pattern on the multilayer ceramic capacitor according to the embodiment in FIGS. 12 and 13.

FIG. 14C is a diagram of the electrode pattern on the multilayer ceramic capacitor according to the embodiment in FIGS. 12 and 13.

FIG. 14D is a diagram of the electrode pattern on the multilayer ceramic capacitor according to the embodiment in FIGS. 12 and 13.

FIG. 15A is a diagram of another example electrode pattern on the multilayer ceramic capacitor according to the embodiment in FIGS. 12 and 13.

FIG. 15B is a diagram of another example electrode pattern on the multilayer ceramic capacitor according to the embodiment in FIGS. 12 and 13.

FIG. 15C is a diagram of another example electrode pattern on the multilayer ceramic capacitor according to the embodiment in FIGS. 12 and 13.

FIG. 15D is a diagram of another example electrode pattern on the multilayer ceramic capacitor according to the embodiment in FIGS. 12 and 13.

FIG. 16A is a diagram of another example electrode pattern on the multilayer ceramic capacitor according to the embodiment in FIGS. 12 and 13.

FIG. 16B is a diagram of another example electrode pattern on the multilayer ceramic capacitor according to the embodiment in FIGS. 12 and 13.

FIG. 16C is a diagram of another example electrode pattern on the multilayer ceramic capacitor according to the embodiment in FIGS. 12 and 13.

FIG. 16D is a diagram of another example electrode pattern on the multilayer ceramic capacitor according to the embodiment in FIGS. 12 and 13.

### DESCRIPTION OF EMBODIMENTS

An aerial image display device with the structure that forms the basis of an aerial image display device according to one or more embodiments of the present disclosure will be described first. The structure with a known technique described in Patent Literature 1 prevents breaks or chips of an element by forming external electrodes on an upper surface and the end faces alone of the element and covering the upper surface and the end faces with a coating layer to improve three-dimensional mountability. However, this complex structure obtained through complicated processes may lower the yield.

The structure with a known technique described in Patent Literature 2 has no specified element height and may be used for a thin and less tall element that is three-dimensionally mountable. With the element, or particularly a main surface electrode element including no extension on the end face, the left and right of an active area are not determined due to a misaligned cut position and thus have different widths in the left and right margins, possibly causing warpage during firing easily. This may cause electrical connection failure and mounting defects on boards.

A multilayer ceramic capacitor and a multilayer ceramic capacitor mounting structure with a simple and thinner structure are thus to minimize warpage without lowering mountability.

A multilayer ceramic capacitor and a mounting structure according to one or more embodiments of the present disclosure will now be described with reference to the drawings. The figures referred to below are schematic and are not necessarily drawn to scale relative to, for example, the actual dimensional ratios. The orthogonal XYZ coordinate system is defined herein for ease of explanation.

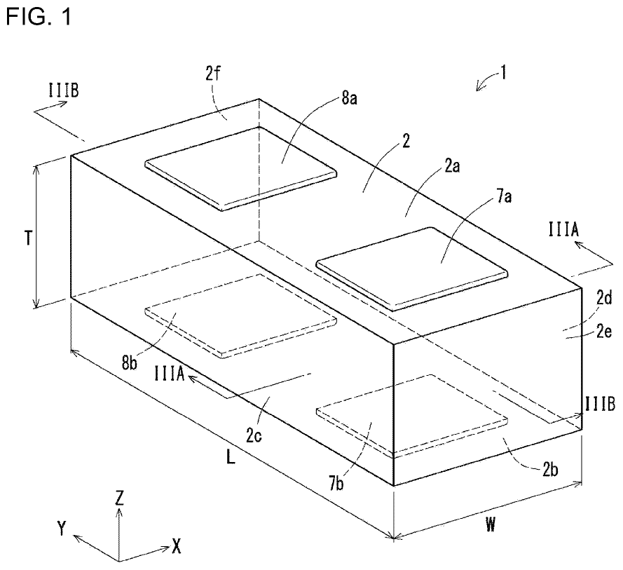

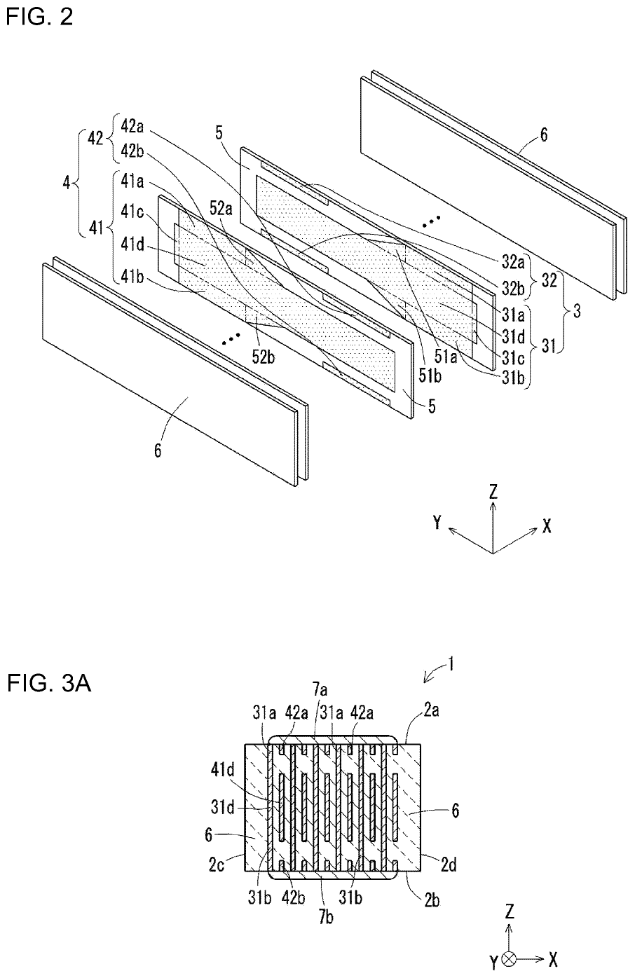

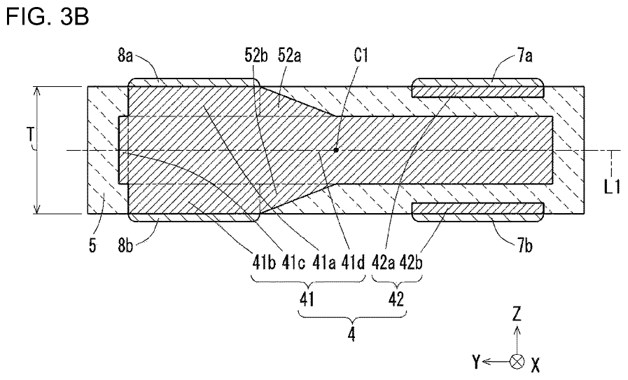

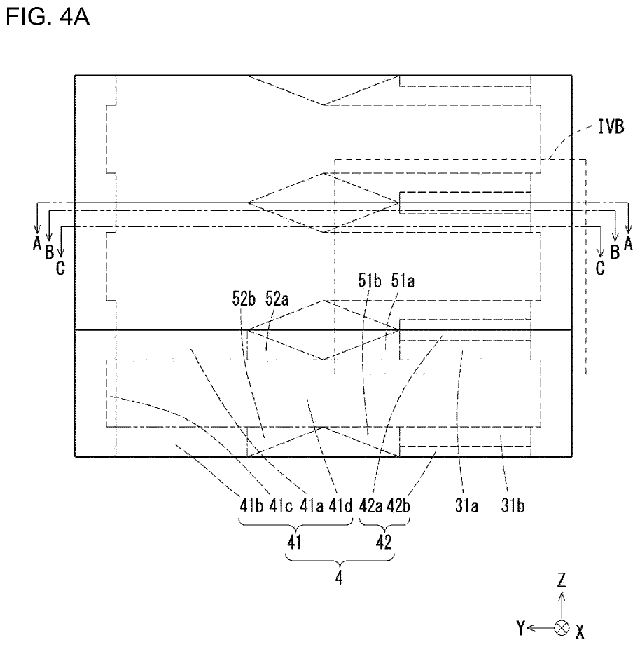

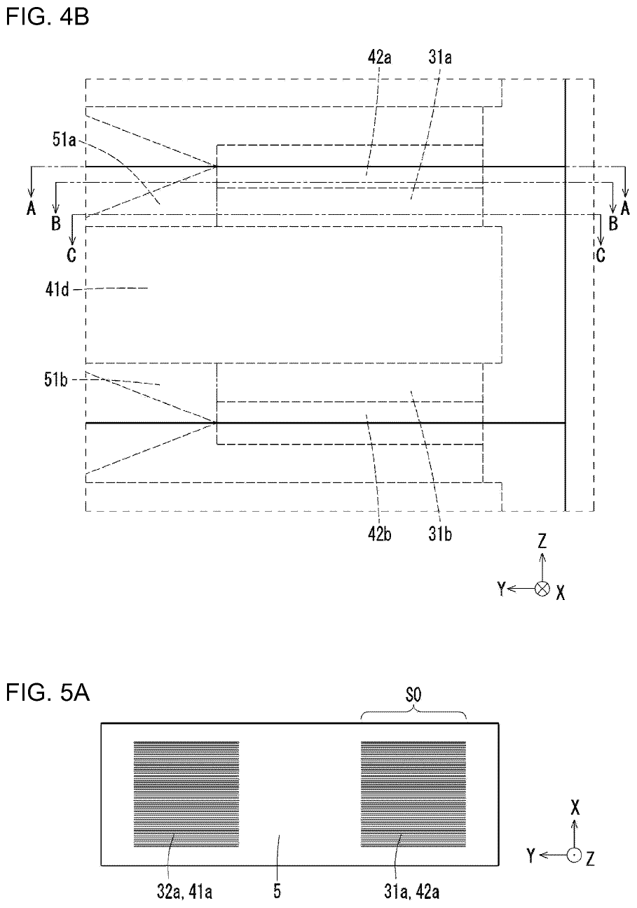

FIG. 1 is a perspective view of a multilayer ceramic capacitor according to an embodiment of the present disclosure. FIG. 2 is an exploded perspective view of the multilayer ceramic capacitor according to the embodiment of the present disclosure. FIG. 3A is a cross-sectional view taken along section line IIIA-IIIA in FIG. 1. FIG. 3B is a cross-sectional view taken along section line IIIB-IIIB in FIG. 1. FIG. 4A is a side view of electrode patterns on three multilayer ceramic capacitors. FIG. 4B is an enlarged view of a part IVB in FIG. 4A. Note that internal electrodes located inside a body are not illustrated in FIG. 1. Note that external electrodes located on surfaces of the body are not illustrated in FIG. 2. The section lines A-A, B-B, and C-C in FIGS. 4A and 4B each correspond to the cut lines of a stack of the three ceramic capacitors before firing.

In the present embodiment, a multilayer ceramic capacitor 1 includes a body 2 being a substantially rectangular prism. The body 2 includes first internal electrodes 3 and second internal electrodes 4 alternately stacked in a first direction X with rectangular dielectric layers 5 between the first internal electrodes 3 and the second internal electrodes 4. The body 2 includes first electrodes and second electrodes alternately stacked in the first direction X with the rectangular dielectric layers 5 between the first electrodes and the second electrodes. The body 2 includes a first surface 2a, a second surface 2b, a first side surface 2c, a second side surface 2d, a first end face 2e, and a second end face 2f. The multilayer ceramic capacitor 1 includes a first external electrode 7a and a second external electrode 8a on the first surface 2a and a third external electrode 7b and a fourth external electrode 8b on the second surface 2b.

The first surface 2a and the second surface 2b are perpendicular to the first direction X and opposite to each other in a second direction Z parallel to a width direction of the dielectric layers 5. The first side surface 2c and the second side surface 2d are opposite to each other in the first direction X. The first end face 2e and the second end face 2f are opposite to each other in a third direction Y parallel to a length direction of the dielectric layers 5 perpendicular to the first direction X and the second direction Z.

As illustrated in FIG. 2, each of the first internal electrodes 3 includes a first portion 31 including a first capacitance portion 31d, a first extension 31a, and a second extension 31b. As illustrated in FIG. 2, each of the second internal electrodes 4 includes a second portion 41 including a second capacitance portion 41d, a third extension 41a, and a fourth extension 41b. The first extension 31a extends to the first surface 2a and is connected to the first external electrode 7a, and the second extension 31b extends to the second surface 2b and is connected to the third external electrode 7b. The third extension 41a extends to the first surface 2a and is connected to the second external electrode 8a, and the fourth extension 41b extends to the second surface 2b and is connected to the fourth external electrode 8b.

The first electrode includes a first inspection electrode 51a including at least one side connected to the intersection between the first capacitance portion 31d and the first extension 31a, and a second inspection electrode 51b including at least one side connected to the intersection between the first capacitance portion 31d and the second extension 31b. The second electrode includes a third inspection electrode 52a including at least one side connected to the intersection between the second capacitance portion 41d and the third extension 41a, and a fourth inspection electrode 52b including at least one side connected to the intersection between the second capacitance portion 41d and the fourth extension 41b.

Each of the first internal electrodes 3 further includes a first dummy portion 32 electrically isolated from the first portion 31. Each of the second internal electrodes 4 further includes a second dummy portion 42 electrically isolated from the second portion 41. The first dummy portion 32 includes a first dummy extension 32a extending to the first surface 2a and a second dummy extension 32b extending to the second surface 2b. The second dummy portion 42 includes a third dummy extension 42a extending to the first surface 2a and a fourth dummy extension 42b extending to the second surface 2b. The first dummy extension 32a is connected to the second external electrode 8a. The second dummy extension 32b is connected to the fourth external electrode 8b. The third dummy extension 42a is connected to the first external electrode 7a. The fourth dummy extension 42b is connected to the third external electrode 7b.

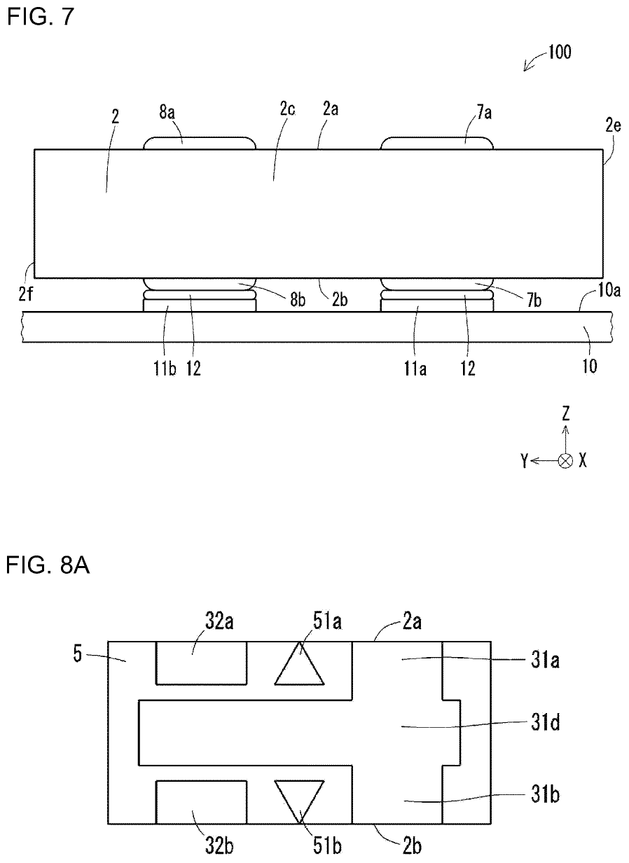

This structure allows the multilayer ceramic capacitor 1 and a multilayer ceramic capacitor mounting structure 100 (refer to FIG. 7) to have a simple and thinner structure having minimized warpage without lowering mountability.

The multilayer ceramic capacitor 1 described above includes the body 2, the first external electrode 7a, the second external electrode 8a, the third external electrode 7b, and the fourth external electrode 8b. The first external electrode 7a, the second external electrode 8a, the third external electrode 7b, and the fourth external electrode 8b may hereafter be collectively referred to as external electrodes 7 and 8.

The first internal electrodes 3 and the second internal electrodes 4 are stacked alternately in the first direction X with the dielectric layers 5 between them, as illustrated in FIG. 2. The first internal electrodes 3 and the second internal electrodes 4 may be hereafter collectively referred to as internal electrodes 3 and 4.

The first internal electrodes 3 and the second internal electrodes 4 are made of a conductive material. The first internal electrodes 3 and the second internal electrodes 4 may be made of, for example, a metal such as nickel (Ni), copper (Cu), silver (Ag), tin (Sn), platinum (Pt), palladium (Pd), or gold (Au), an alloy containing any of these metals, or a common material powder mainly containing the same ceramic powder as the dielectric layers 5.

The dielectric layers 5 are made of an insulating material. The dielectric layers 5 may be made of a dielectric material (ceramic material) such as barium titanate (BaTiO₃), calcium titanate (CaTiO₃), strontium titanate (SrTiO₃), or barium zirconate (BaZrO₃) as a main component. Note that the main component herein refers to a component with a highest concentration (mol %) in a target material or a target member.

The main component of the dielectric layers 5 may be a high dielectric constant material. The high dielectric constant material may be, for example, a perovskite ferroelectric material containing any of the above dielectric materials. The dielectric layers 5 may contain a rare earth element such as yttrium (Y), dysprosium (Dy), holmium (Ho), gadolinium (Gd), or terbium (Tb). The dielectric layers 5 may also contain a glass component mainly containing SiO₂ (silica) as a sintering aid.

The first direction X may also be referred to as a stacking direction. The second direction Z may also be referred to as a height direction. The third direction Y may also be referred to as a length direction.

The side surfaces 2c and 2d of the body 2 are the surfaces of side covers 6, as illustrated in FIG. 2. This protects the first internal electrodes 3 and the second internal electrodes 4 from the external environment. The side covers 6 may each include one or more dielectric layers. The dielectric layers in the side covers 6 may have the same composition, dimensions, and other features as the dielectric layers 5.

The third extension 41a and the fourth extension 41b extend from the second capacitance portion 41d. The first capacitance portion 31d in the first portion 31 and the second capacitance portion 41d overlap each other when viewed in the first direction (stacking direction) X. Any potential difference between the first capacitance portion 31d and the second capacitance portion 41d generates a capacitance in each of the dielectric layers 5 located between the first capacitance portion 31d and the second capacitance portion 41d.

As illustrated in FIG. 3A, the first external electrode 7a connects multiple first extensions 31a with one another. The first external electrode 7a covers the multiple first extensions 31a. The second external electrode 8a connects the multiple third extensions 41a with one another in the same manner as or in a similar manner to the first external electrode 7a illustrated in FIG. 3A. The second external electrode 8a covers the multiple third extensions 41a.

As illustrated in FIGS. 3A and 3B, the third external electrode 7b connects the multiple second extensions 31b with one another. The third external electrode 7b covers the multiple second extensions 31b. The fourth external electrode 8b connects the multiple fourth extensions 41b with one another in the same manner as or in a similar manner to the third external electrode 7b illustrated in FIGS. 3A and 3B. The fourth external electrode 8b covers the multiple fourth extensions 41b.

The first external electrode 7a, the second external electrode 8a, the third external electrode 7b, and the fourth external electrode 8b may each include one or more conductive layers. A first conductive layer in contact with the first surface 2a and the second surface 2b (specifically, surfaces connected to the internal electrodes 3 and 4) may be formed using, for example, a thin film deposition technique such as plating, sputtering, or vapor deposition, or a thick film deposition technique such as screen printing or gravure printing. The second conductive layer, the third conductive layer, and other layers on the first conductive layer may be formed using a thin film deposition technique such as electroplating. The first conductive layer may be made of, for example, a metal such as Ni, Cu, Ag, Pd, or Au, or an alloy containing any of these metals. The second conductive layer, the third conductive layer, and other conductive layers may be made of, for example, a metal such as Ni, Cu, Au, or Sn.

The first dummy extension 32a connected to the second external electrode 8a increases the strength of connection between the body 2 and the second external electrode 8a, thus increasing the reliability of electrical connection between each of the second internal electrodes 4 and the second external electrode 8a. The second dummy extension 32b connected to the fourth external electrode 8b increases the strength of connection between the body 2 and the fourth external electrode 8b, thus increasing the reliability of electrical connection between each of the second internal electrodes 4 and the fourth external electrode 8b.

The first dummy extension 32a may overlap the third extension 41a when viewed in the stacking direction (X-direction). The second external electrode 8a can thus be rectangular with its length in the first direction X and its width smaller in the second direction Z, as illustrated in FIG. 1. This facilitates formation of the second external electrode 8a and reduces the likelihood of a leakage current between the second external electrode 8a and another external electrode different in polarity from the second external electrode 8a.

The second dummy extension 32b may overlap the fourth extension 41b when viewed in the stacking direction (X-direction). The fourth external electrode 8b can thus be rectangular with its length in the first direction X and its width smaller in the third direction Y, as illustrated in FIG. 1. This facilitates formation of the fourth external electrode 8b. This also reduces the likelihood of a leakage current between the fourth external electrode 8b and another external electrode different in polarity from the fourth external electrode 8b.

The third dummy extension 42a extends to the first surface 2a and is connected to the first external electrode 7a to increase the strength of connection between the body 2 and the first external electrode 7a, thus increasing the reliability of electrical connection between each of the first internal electrodes 3 and the first external electrode 7a.

The fourth dummy extension 42b extends to the second surface 2b and is connected to the third external electrode 7b to increase the strength of connection between the body 2 and the third external electrode 7b, thus increasing the reliability of electrical connection between each of the first internal electrodes 3 and the third external electrode 7b.

The third dummy extension 42a may overlap the first extension 31a when viewed in the stacking direction (X-direction). The first external electrode 7a can thus be rectangular with its length in the first direction X and its width smaller in the third direction Y, as illustrated in FIG. 1. This facilitates formation of the first external electrode 7a. This also reduces the likelihood of a leakage current between the first external electrode 7a and another external electrode different in polarity from the first external electrode 7a.

The fourth dummy extension 42b may overlap the second extension 31b when viewed in the stacking direction (X-direction). The third external electrode 7b can thus be rectangular with its length in the first direction X and its width smaller in the third direction Y, as illustrated in FIG. 1. This facilitates formation of the third external electrode 7b. This also reduces the likelihood of a leakage current between the third external electrode 7b and another external electrode different in polarity from the third external electrode 7b.

When viewed in a direction perpendicular to the first surface 2a, the first external electrode 7a and the third external electrode 7b may overlap, and the second external electrode 8a and the fourth external electrode 8b may overlap. In this case, as illustrated in FIG. 3B, each of the first internal electrodes 3 and the second internal electrodes 4 is symmetric with respect to a line L1 extending in the length direction (Y-direction) through centroids CI of the side surfaces 2c and 2d. This reduces warpage of the body 2 resulting from the difference in firing shrinkage between the metal or alloy material for the internal electrodes 3 and 4 and the ceramic material for the dielectric layers 5 in fabricating the body 2. This increases the reliability of the connection between the multilayer ceramic capacitor 1 and an external substrate.

When an effective height H is less than or equal to 80% of a height T, the likelihood of misalignment in cutting that can lower the production yield of stacks before firing is reduced. When the effective height H is less than or equal to 70% of the height T, the likelihood of delamination after firing resulting from bonding at margins is reduced.

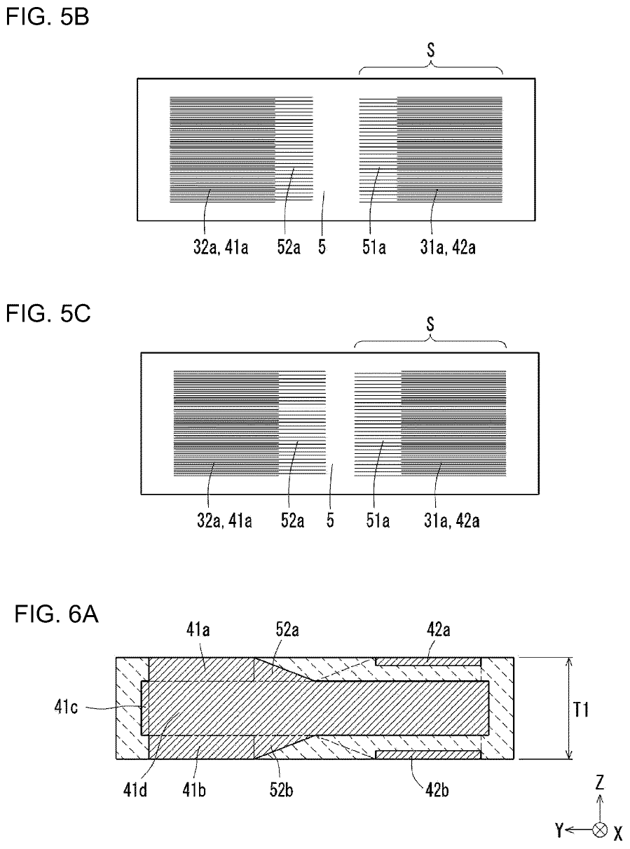

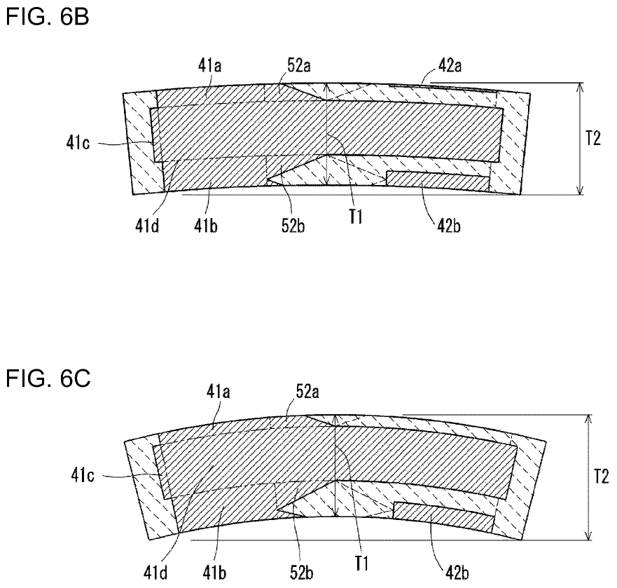

FIG. 4A is a side view of the electrode patterns on the three multilayer ceramic capacitors. FIG. 4B is an enlarged view of the part IVB in FIG. 4A. FIGS. 5A to 5C are cross-sectional views taken along section lines A-A, B-B, and C-C in FIGS. 4A and 4B. FIG. 5A is a cross-sectional view taken along section line A-A in FIG. 4A. FIG. 5B is a cross-sectional view taken along section line B-B in FIG. 4A. FIG. 5C is a cross-sectional view taken along section line C-C in FIG. 4A. FIGS. 6A to 6C are cross-sectional views of the multilayer ceramic capacitor after firing as viewed from a perpendicular plane (first direction X) different from adjacent end faces taken along section lines A-A, B-B, and C-C in FIG. 4A. FIG. 6A is a cross-sectional view of the multilayer ceramic capacitor after firing as viewed in the first direction X perpendicular to section line A-A in FIG. 4A. FIG. 6B is a cross-sectional view of the multilayer ceramic capacitor after firing as viewed in the first direction X perpendicular to section line B-B in FIG. 4A. FIG. 6C is a cross-sectional view of the multilayer ceramic capacitor after firing as viewed in the first direction X perpendicular to section line C-C in FIG. 4A. Note that FIG. 6A is a view of the multilayer ceramic capacitor having a warpage D of 0%, FIG. 6B is a view of the multilayer ceramic capacitor having the warpage D of less than or equal to 10%, and FIG. 6C is a view of the multilayer ceramic capacitor having the warpage D of greater than or equal to 10%. Note that the section lines A-A, B-B, and C-C in FIGS. 4A and 4B indicate the positions for cutting the three multilayer ceramic capacitors into three sections. FIGS. 5A to 5C are views of cut surfaces exposed after cutting the stack of the three multilayer ceramic capacitors. FIGS. 6A to 6C are views illustrating a change in warpage of a fired stack due to different areas of exposed cut surfaces of the internal electrodes.

An expansion rate M based on M={(S/S0)−1}×100 is within 0≤M≤36% when the warpage D is less than or equal to 10%, where the warpage D is T1/T2, T1 is a substantial thickness of the body 2 after firing, T2 is the distance between two parallel planes in contact with opposite ends of the body 2 after firing in the thickness direction and parallel to the thickness direction of the two parallel planes, S is a measured area of the portions of the first extension 31a and the first inspection electrode 51a exposed on the first surface 2a before firing, S0 is a design area of the portions of the first extension 31a and the first inspection electrode 51a exposed on the first surface 2a, and M is the expansion rate of the portions of the first extension 31a and the first inspection electrode 51a exposed on the first surface 2a resulting from firing. This allows determination as to whether each multilayer ceramic capacitor 1 after firing is acceptable or defective in a raw stack inspection process before firing, thus increasing production efficiency.

An example method for manufacturing the multilayer ceramic capacitor 1 will now be described.

As a material for the dielectric layers 5, a powder containing a dielectric material such as BaTiO₃, CaTiO₃, or SrTiO₃, or a mixture of these as a main component is prepared, and an organic vehicle is added to the powder to prepare ceramic slurry. Ceramic green sheets (hereafter also simply referred to as green sheets) are then fabricated using, for example, doctor blading or die coating. Each green sheet may have a thickness of, for example, about 0.5 to 10 μm.

A conductive paste is then prepared as a material for the first internal electrodes 3 and the second internal electrodes 4 using, as a common material, a powder mainly containing a metal such as Ni, Cu, Ag, or Pd, or a mixture of these metal materials mixed with a ceramic powder that is a main component of a dielectric of 1 to 30 parts by weight. Using the prepared conductive paste, a first pattern sheet that is a green sheet with an electrode pattern to be the first internal electrodes 3 printed on its main surface and a second pattern sheet that is a green sheet with an electrode pattern to be the second internal electrodes 4 printed on its main surface are formed. The electrode patterns may be printed by, for example, screen printing or gravure printing.

A predetermined number of first pattern sheets and a predetermined number of second pattern sheets are then alternately stacked on a stack of a predetermined number of ceramic green sheets, and a predetermined number of ceramic green sheets are stacked on the stack of the first pattern sheets and the second pattern sheets to fabricate a temporary stack. The temporary stack is then pressed in the stacking direction to obtain a multilayer base. The temporary stack may be pressed with, for example, a hydrostatic pressing device. The multilayer base is cut at intended positions to obtain a raw base component to be the body 2. The cut raw base component is placed in a pot with an abrasive powder or a medium, and the pot is rotated to round the corners of the base component for polishing. Subsequently, the cut raw base component is degreased in an ambient atmosphere, an inert gas atmosphere, or a reducing atmosphere, and then is fired in a reducing atmosphere. The firing temperature may be, for example, about 1000 to 1300° C. The raw base component is then reoxidized in a nitrogen atmosphere. The method may include placing the reoxidized base component in a pot with an abrasive powder or a medium, and then rotating the pot to round the corners of the base component and remove firing burrs of the base component for polishing again. Through these processes, the body 2 is obtained.

The first external electrode 7a and the second external electrode 8a are formed on the first surface 2a of the obtained body 2, and the third external electrode 7b and the fourth external electrode 8b are formed on the second surface 2b of the obtained body 2 to manufacture the multilayer ceramic capacitor 1. The first external electrode 7a and the second external electrode 8a can be formed using the thin film deposition technique or the thick film deposition technique described above.

The mounting structure 100 according to one embodiment of the present disclosure will now be described. FIG. 7 is a side view of the mounting structure according to one embodiment of the present disclosure. In the present embodiment, the mounting structure 100 includes the multilayer ceramic capacitor 1 and a substrate 10. The substrate 10 includes a mounting surface 10a. The substrate 10 includes at least one first substrate electrode 11a and at least one second substrate electrode 11b located on the mounting surface 10a as illustrated in FIG. 7. An electrical circuit electrically connected to the multilayer ceramic capacitor 1 may be located on the mounting surface 10a.

The multilayer ceramic capacitor 1 is mounted on the mounting surface 10a with the side surfaces 2c and 2d perpendicular to the mounting surface 10a. In other words, the multilayer ceramic capacitor 1 is mounted on the mounting surface 10a with the first internal electrodes 3 and the second internal electrodes 4 perpendicular to the mounting surface 10a.

In the multilayer ceramic capacitor 1, at least one of the first external electrode 7a or the third external electrode 7b is electrically connected to the first substrate electrode 11a, and at least one of the second external electrode 8a or the fourth external electrode 8b is electrically connected to the second substrate electrode 11b. The multilayer ceramic capacitor 1 may be mounted on the substrate 10 by, for example, bonding the first external electrode 7a to the first substrate electrode 11a and the second external electrode 8a to the second substrate electrode 11b, each with a conductive bond 12. The conductive bond 12 may be, for example, a solder material or a brazing material.

The multilayer ceramic capacitor 1 may be mounted on the substrate 10 by, for example, electrically connecting the first external electrode 7a to one of two first substrate electrodes 11a and the third external electrode 7b to the other of the two first substrate electrodes 11a, and electrically connecting the second external electrode 8a to one of two second substrate electrodes 11b and the fourth external electrode 8b to the other of the two second substrate electrodes 11b. In this case, the first external electrode 7a may be bonded to the corresponding first substrate electrode 11a and the second external electrode 8a to the corresponding second substrate electrode 11b, each with the conductive bond 12. The third external electrode 7b may be bonded to the corresponding first substrate electrode 11a and the fourth external electrode 8b to the corresponding second substrate electrode 11b, each with a connector such as a bonding wire.

The multilayer ceramic capacitor 1 including the first external electrode 7a and the second external electrode 8a may be mounted on the mounting surface 10a by boding the third external electrode 7b to the first substrate electrode 11a and the fourth external electrode 8b to the second substrate electrode 11b as illustrated in FIG. 7.

The mounting structure 100 including the multilayer ceramic capacitor 1 is thus highly reliable.

A large number of multilayer ceramic capacitors 1 illustrated in FIGS. 1 to 6C were manufactured in an example. The manufacturing procedure is described below.
(1) A material mainly containing barium titanate is shaped into a green sheet.
(2) The internal electrodes illustrated in FIGS. 3A and 3B and anchor tabs that facilitate formation of external electrodes on the upper and lower main surfaces (the first surface 2a and the second surface 2b) are formed on the green sheet by gravure printing.
(3) The internal electrodes are patterned to allow the external electrodes to have the same polarity on the upper and lower main surfaces.
(4) To indicate a cut position for cutting after stacking, the internal electrodes include patterns for inspecting misalignment in cutting are formed with their areas extending from the extension toward the active portion.
(5) For the internal electrodes and the anchor tabs, a Ni conductive paste is selected.
(6) The patterned sheets are stacked on one another to have their sections along section lines A-A and B-B in FIGS. 4A and 4B alternating with each other, and cover layers are placed on the outermost surfaces (leftmost and rightmost side surfaces) of the stack.
(7) The stack before firing is cut at intended positions, and then the cut stacks before firing are determined whether each stack is acceptable or defective with a visual inspection device. The distance between the electrodes is set to 30 to 100% of a design value as a determination condition.
(8) The obtained raw component body undergoes barrel polishing in a container with an abrasive powder or a medium to obtain a surface-treated raw component body.
(9) A selected surface-treated raw component body before firing is degreased in an ambient atmosphere, an inert gas atmosphere, or a reducing atmosphere, and then is fired at 1100° C. in a reducing atmosphere.
(10) A ceramic body is thus obtained and is thermally treated in a nitrogen atmosphere, and then again undergoes barrel polishing in the container with an abrasive powder or a medium to remove firing burrs, obtaining a ceramic component body with no firing burrs.
(11) The obtained ceramic component body includes a surface on which the internal electrodes and the anchor tabs are exposed as a main surface of the product. A first layer of the external electrodes is formed by direct electroless Cu plating. Second and third external electrode layers of Ni and Sn are then formed on the first layer by normal electroplating.
(12) The ceramic component body may include an extension that forms the second and third external electrodes based on the specifications of an interposer. The first layer of the external electrodes may not be plated with multiple layers of, for example, Ni, Sn, and solder.

The dimensions of the multilayer ceramic capacitor in the example are described below.
A distance L between the end faces is 1.9±0.2 mm.
A distance W between the side surfaces is 0.7±0.2 mm.
A distance T between the main surfaces is 0.5±0.1 mm.
The warpage in a main surface direction is less than or equal to 4%.
Each layer of the ceramic body has a thickness of 1.2±0.1 μm.

A multilayer ceramic capacitor in a comparative example is manufactured in the procedures (1) to (7) below.
(1) A material mainly containing barium titanate is shaped into a green sheet as in the example described above.
(2) Internal electrodes are formed by gravure printing, and external electrodes are formed by doping to form a sheet with a common multilayer structure.
(3) For the internal electrodes, a Ni conductor paste is selected.
(4) Electrode sheets of two different types are alternately stacked on one another and cover layers are placed on the upper and lower surfaces of the resulting stack.
(5) The stack is cut at intended positions, and then undergoes barrel polishing in a pot with an abrasive powder or a medium. The stack is then degreased in an ambient atmosphere, an inert gas atmosphere, or a reducing atmosphere, and is fired at 1100° C. in a reducing atmosphere.
(6) A ceramic body is thus obtained and is thermally treated in a nitrogen atmosphere, and then undergoes barrel polishing in a container with an abrasive powder or a medium to obtain a ceramic component body.
(7) The obtained ceramic component body includes a first external electrode layer formed by dipping of a conductive Cu paste on a surface on which the internal electrodes are exposed, and second and third external electrode layers of, for example, Ni and Sn formed by normal electroplating on the surface of the first external electrode layer.

The dimensions of the multilayer ceramic capacitor in the comparative example are described below.
A distance L between the end faces is 1.9±0.2 mm.
A distance W between the side surfaces is 0.7±0.2 mm.
A distance T between the main surfaces is 0.5±0.1 mm.
Each layer of the ceramic body has a thickness of 1.2±0.1 μm.

The capacitance and the leakage current were measured with an electric characteristic evaluation device, and the values within a tolerance of +15° in capacitance were determined to be acceptable. Of the acceptable products, 100 samples were selected and underwent warpage evaluation. The external defect rate of the samples with a warpage of greater than or equal to 4% was also calculated. Tables 1 and 2 below show the calculation results.

TABLE 1

| | Average | Average | Average | Thickness | | |
|---|---|---|---|---|---|---|
| | value of | value of | value of | of internal | | Internal |
| | dimension | dimension | dimension | electrode | | defect |
| | L | W | T | layer 5 | Warpage | rate |
| Unit | mm | mm | mm | μm | % | % |
| Example | 1.9 | 0.7 | 0.5 | 1.2 | 4.3 | 0 |
| Comparative | 1.9 | 0.7 | 0.5 | 1.2 | 12.1 | 30 |
| example | | | | | | |

TABLE 2

| | | | Comparative |
|---|---|---|---|
| | Unit | Example | example |
| Dimension L | μm | 1900 | 1900 |
| Dimension W | μm | 700 | 700 |
| Dimension T | μm | 500 | 500 |
| SM | μm | 122 | 100 |
| TM | μm | 100 | 122 |
| Effective dimension L | μm | 1660 | 1660 |
| Effective dimension W | μm | 320 | 500 |
| Effective dimension T | μm | 500 | 320 |
| Effective S | μm² | 424960 | 830000 |
| td | μm | 1.2 | 1.2 |
| te | μm | 0.6 | 0.6 |
| n | Layer | 278 | 122 |

The average warpage of 100 acceptable products of the multilayer ceramic capacitor in the example and the average warpage of 100 acceptable products of the multilayer ceramic capacitor in the comparative example were calculated. Additionally, the acceptable products were cut and their cross sections were visually inspected for internal defects. The results reveal that the 100 acceptable products of the multilayer ceramic capacitor in the example have an average warpage of 4.3% and no internal defects are observed, whereas the 100 acceptable products of multilayer ceramic capacitor in the comparative example have an average warpage of 12.1% and internal defects resulting from warpage deformation are observed in 5 of the 100 acceptable products. The results indicate that the raw stack having an extension electrode area greater than or equal to 30% in the visual inspection are to be removed to obtain the multilayer ceramic capacitor with less external warpage and deformation in the example. This also allows determination as to whether the multilayer ceramic capacitor has internal structural defects. In one or more embodiments of the present disclosure, the multilayer ceramic capacitor 1 can thus be efficiently manufactured with high reliability.

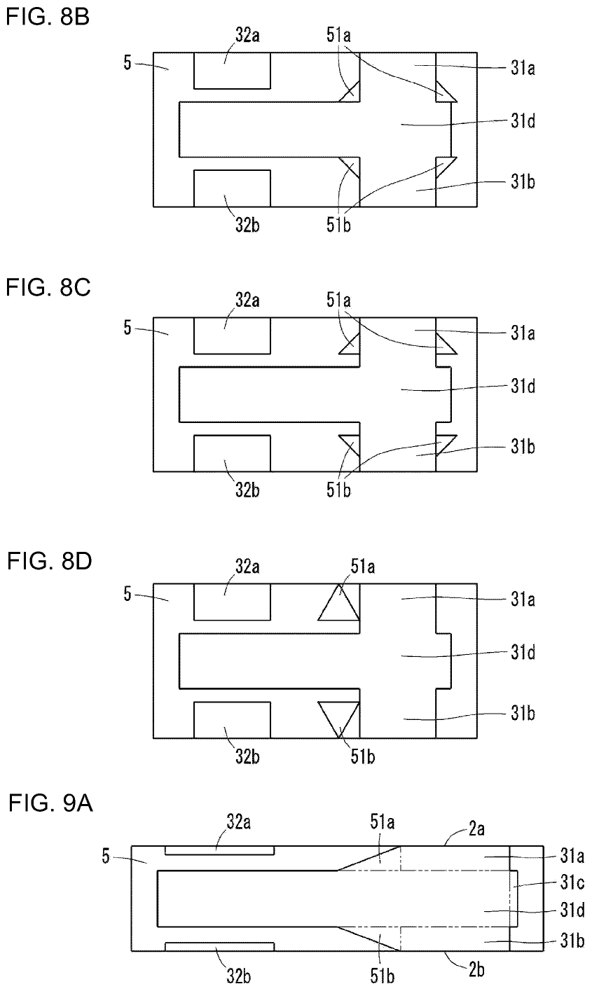

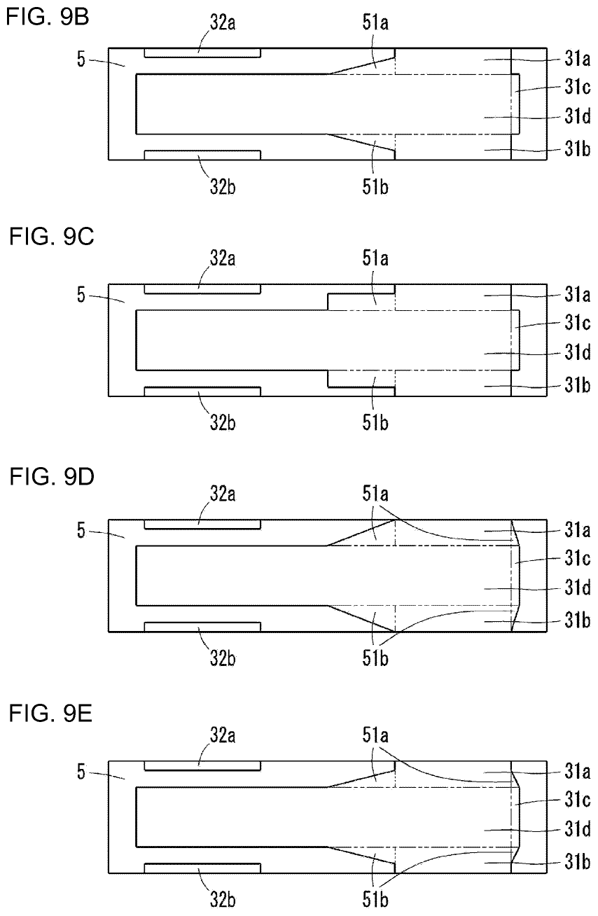

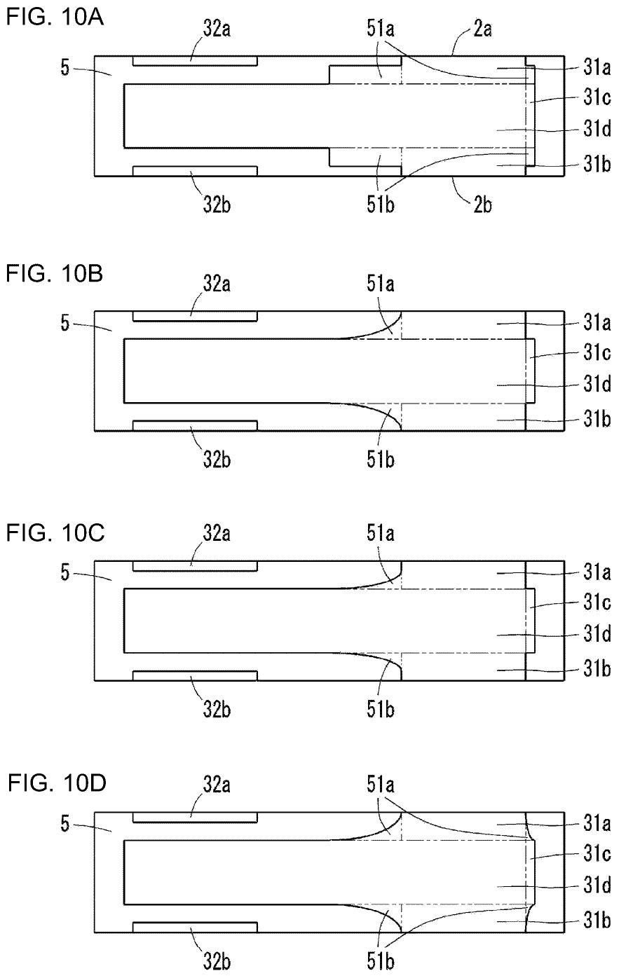

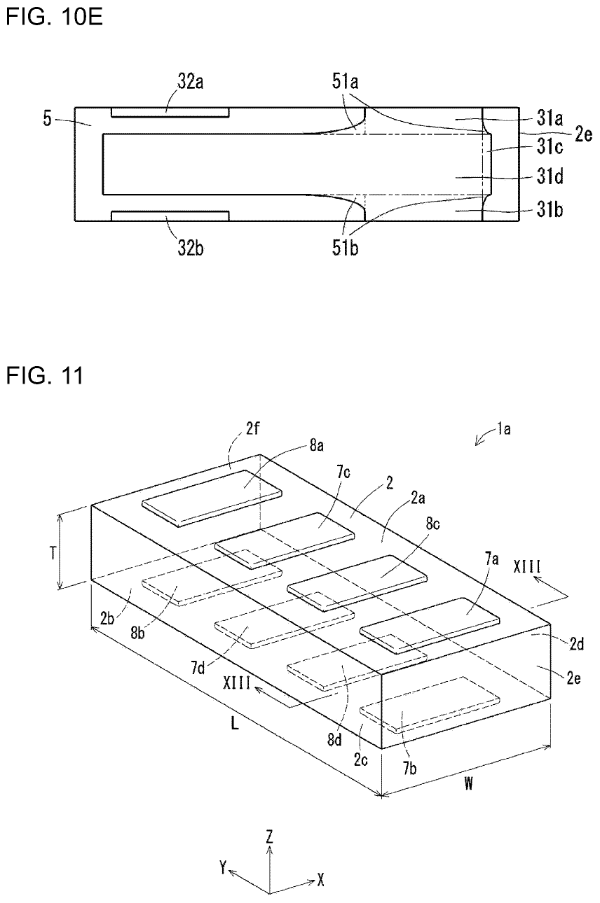

FIGS. 8A to 8D are diagrams of the first inspection electrode(s) 51a and the second inspection electrode(s) 51b, each illustrating their patterns. FIGS. 9A to 9E are diagrams of the first inspection electrode(s) 51a and the second inspection electrode(s) 51b, each illustrating their other patterns. FIGS. 10A to 10E are diagrams of the first inspection electrode(s) 51a and the second inspection electrode(s) 51b, each illustrating their still other patterns. As illustrated in FIG. 8A, the first inspection electrode 51a and the second inspection electrode 51b described above may each be equilateral triangular and be spaced from the internal electrodes 3 to be insulated from the internal electrodes 3. As illustrated in FIG. 8B, two first inspection electrodes 51a may each be right triangular and integrally continuous with both sides of the first extension 31a and the first capacitance portion 31d. Two second inspection electrodes 51b may be right triangular and integrally continuous with both sides of the second extension 31b and the first capacitance portion 31d. As illustrated in FIG. 8C, the two first inspection electrodes 51a may each be right triangular, spaced from the first capacitance portion 31d, and simply in contact with both sides of the first extension 31a. Two second inspection electrodes 51b may each be right triangular, spaced from the first capacitance portion 31d, and simply in contact with both sides of the second extension 31b. As illustrated in FIG. 8D, one first inspection electrode 51a and one second inspection electrode 51b may each be equilateral triangular, spaced from the first capacitance portion 31d, and in point contact with the first and second extensions 31a and 31b.

As illustrated in FIG. 9A, the first inspection electrode 51a may be right triangular and continuous with the first extension 31a and the first capacitance portion 31d. The second inspection electrode 51b may be right triangular and continuous with the second extension 31b and the first capacitance portion 31d. As illustrated in FIG. 9B, the first inspection electrode 51a may be right triangular, located inward from the first surface 2a, and continuous with the first extension 31a and the first capacitance portion 31d. The second inspection electrode 51b may be right triangular, located inward from the second surface 2b, and continuous with the second extension 31b and the first capacitance portion 31d.

As illustrated in FIG. 9C, the first inspection electrode 51a may be rectangular and continuous with the first extension 31a and the first capacitance portion 31d. The second inspection electrode 51b may be rectangular and continuous with the second extension 31b and the first capacitance portion 31d. As illustrated in FIG. 9D, for a multilayer ceramic capacitor including a first active electrode extension 31c, the first inspection electrode 51a may include a right-triangular portion continuous with the first extension 31a and the first capacitance portion 31d and a right-triangular portion continuous with the first extension 31a and the first active electrode extension 31c. The second inspection electrode 51b may include a right-triangular portion continuous with the second extension 31b and the first capacitance portion 31d and a right-triangular portion continuous with the second extension 31b and the first active electrode extension 31c.

As illustrated in FIG. 9E, for the multilayer ceramic capacitor including the first active electrode extension 31c, the first inspection electrode 51a may include a right-triangular portion continuous with the first extension 31a and the first capacitance portion 31d and located inward from the first surface 2a and a right-triangular portion continuous with the first extension 31a and the first active electrode extension 31c and located inward from the first surface 2a. The second inspection electrode 51b may include a right-triangular portion continuous with the second extension 31b and the first capacitance portion 31d and located inward from the second surface 2b and a right-triangular portion continuous with the second extension 31b and the first active electrode extension 31c and located inward from the second surface 2b.

As illustrated in FIG. 10A, for the multilayer ceramic capacitor including the first active electrode extension 31c, the first inspection electrode 51a may include a rectangular portion continuous with the first extension 31a and the first capacitance portion 31d and located inward from the first surface 2a and a rectangular portion continuous with the first extension 31a and the first active electrode extension 31c and located inward from the first surface 2a. The second inspection electrode 51b may include a rectangular portion continuous with the second extension 31b and the first capacitance portion 31d and located inward from the second surface 2b and a rectangular portion continuous with the second extension 31b and the first active electrode extension 31c and located inward from the second surface 2b. As illustrated in FIG. 10B, the first inspection electrode 51a may include a triangular portion continuous with the first extension 31a and the first capacitance portion 31d. The triangular portion may have its oblique side curved inward from the first surface 2a. The second inspection electrode 51b may include a triangular portion continuous with the second extension 31b and the first capacitance portion 31d. The triangular portion may have its oblique side curved inward from the second surface 2b.

As illustrated in FIG. 10C, the first inspection electrode 51a may include a triangular portion continuous with the first extension 31a and the first capacitance portion 31d and located inward from the first surface 2a. The triangular portion may have its oblique side curved inward. The second inspection electrode 51b may include a triangular portion continuous with the second extension 31b and the first capacitance portion 31d and located inward from the second surface 2b. The triangular portion may have its oblique side curved inward. As illustrated in FIG. 10D, the first inspection electrode 51a may include a triangular portion continuous with the first extension 31a and the first capacitance portion 31d. The first inspection electrode 51a may have its oblique side curved inward from the first surface 2a. The first inspection electrode 51a also include a triangular portion continuous with the first extension 31a and the first active electrode extension 31c. The triangular portion may have its oblique side curved inward from the first end face 2e. The second inspection electrode 51b may include a triangular portion continuous with the second extension 31b and the first capacitance portion 31d. The triangular portion may have its oblique side curved inward from the second surface 2b. The second inspection electrode 51b may include a triangular portion continuous with the second extension 31b and the first active electrode extension 31c. The triangular portion may have its oblique side curved inward and from the first end face 2e.

As illustrated in FIG. 10E, the first inspection electrode 51a may include a triangular portion continuous with the first extension 31a and the first capacitance portion 31d and located inward from the first surface 2a. The triangular portion may have its oblique side curved inward. The first inspection electrode 51a may include a triangular portion continuous with the first extension 31a and the first active electrode extension 31c and located inward from the first end face 2e. The triangular portion may have its oblique side curved inward. The second inspection electrode 51b may include a portion continuous with the second extension 31b and the first capacitance portion 31d and located inward from the second surface 2b. The triangular portion may have its oblique side curved inward. The second inspection electrode 51b may include a portion continuous with the second extension 31b and the first active electrode extension 31c and located inward from the first end face 2e. The triangular portion may have its oblique side curved inward.

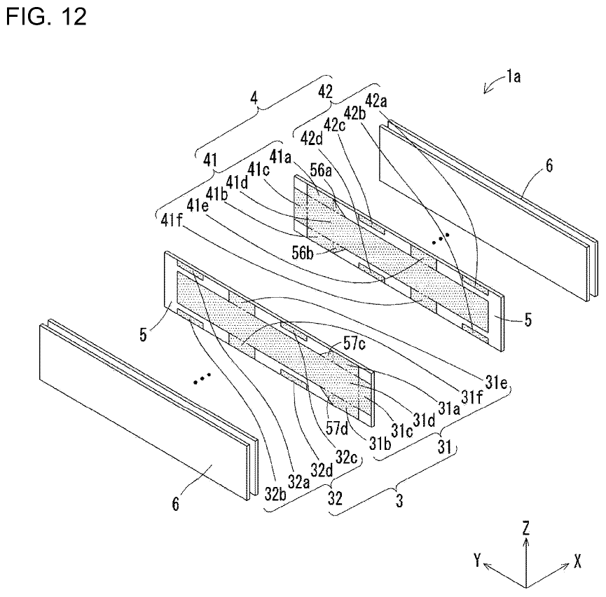

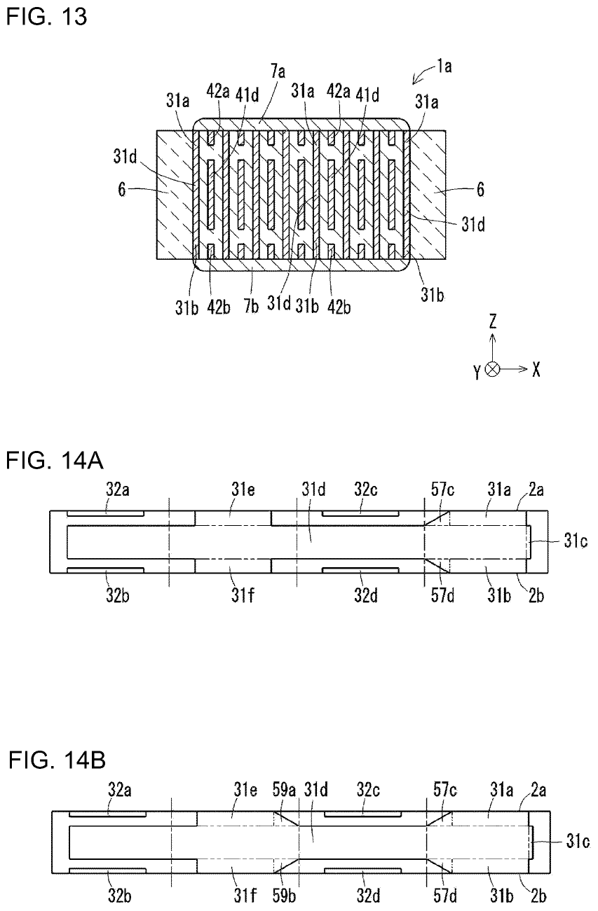

The advantageous effects of the present disclosure may be applicable to a multilayer ceramic capacitor including no external electrode for inspection on the end faces and including multiple terminals on the first surface 2a and the second surface 2b as upper and lower surfaces of the component. For example, FIG. 11 is a perspective view of a multilayer ceramic capacitor 1a according to another embodiment of the present disclosure. The multilayer ceramic capacitor 1a includes four terminals on each of the first surface 2a and the second surface 2b as the upper and lower surfaces of the component. FIG. 12 is an exploded perspective view of the multilayer ceramic capacitor 1a according to the other embodiment of the present disclosure. FIG. 13 is a cross-sectional view of the multilayer ceramic capacitor 1a according to the other embodiment of the present disclosure. FIG. 13 is a cross-sectional view taken along section line XIII-XIII in FIG. 11. Note that the same reference numerals denote the components corresponding to those in the above embodiment.

In the present embodiment, the multilayer ceramic capacitor 1a includes, in the same manner as or in a similar manner to the multilayer ceramic capacitor 1 described above, the body 2 being a substantially rectangular prism. The body 2 includes the first internal electrodes 3 and the second internal electrodes 4 alternately stacked in the first direction X with the rectangular dielectric layers 5 between the first internal electrodes 3 and the second internal electrodes 4. The body 2 includes the first electrodes and the second electrodes alternately stacked in the first direction X with the rectangular dielectric layers 5 between the first electrodes and the second electrodes. The body 2 includes the first surface 2a, the second surface 2b, the first side surface 2c, the second side surface 2d, the first end face 2e, and the second end face 2f. The multilayer ceramic capacitor 1 includes the first external electrode 7a and the second external electrode 8a on the first surface 2a and the third external electrode 7b and the fourth external electrode 8b on the second surface 2b.

In the present embodiment, the multilayer ceramic capacitor 1a is the multilayer ceramic capacitor 1 described above further including a fifth external electrode 7c, a sixth external electrode 8c, a seventh external electrode 7d, an eighth external electrode 8d, a fifth extension 31e, a sixth extension 31f, a fifth dummy electrode 32c, and a sixth dummy electrode 32d.

In the same manner as or in a similar manner to the first inspection electrode 51a and the second inspection electrodes 51b in FIGS. 1, 2, 3A, 3B, 4A, 4B, 5A to 5C, 6A to 6C, 7, 8A to 8D, 9A to 9E, and 10A to 10E, the multilayer ceramic capacitor 1a includes a fifth inspection electrode 57c at the intersection between the first capacitance portion 31d and the first extension 31a, a seventh inspection electrode 57d at the intersection between the first capacitance portion 31d and the second extension 31b, a sixth inspection electrode 56a at the intersection between the second capacitance portion 41d and the third extension 41a, and an eighth inspection electrode 56b at the intersection between the second capacitance portion 41d and the fourth extension 41b.

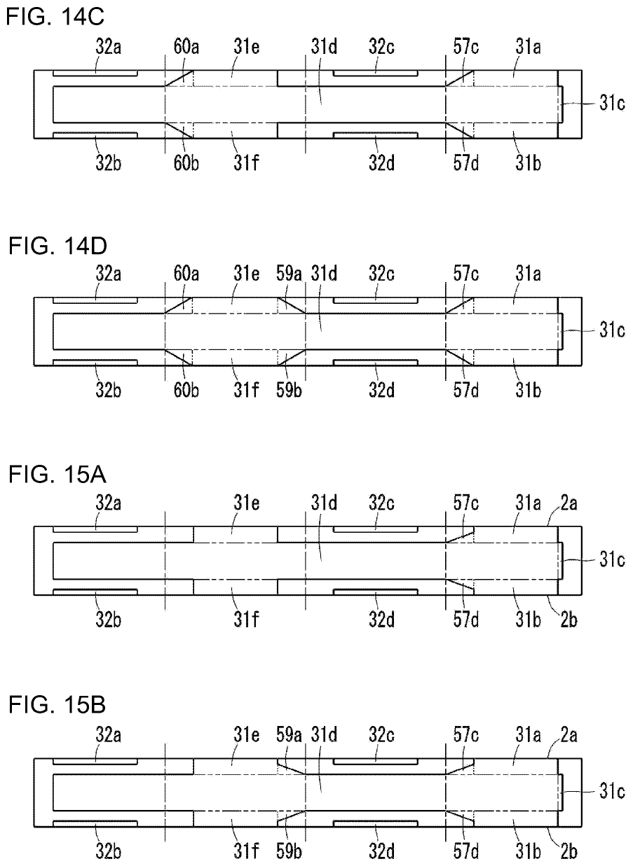

FIGS. 14A to 14D are diagrams of electrode patterns on the multilayer ceramic capacitor 1a according to the embodiment illustrated in FIGS. 12 and 13. Note that the same reference numerals denote the components corresponding to those in the above embodiment. As illustrated in FIG. 14A, the multilayer ceramic capacitor 1a may include the right-triangular fifth inspection electrode 57c continuous with the intersection between the first capacitance portion 31d and the first extension 31a and the right-triangular seventh inspection electrode 57d continuous with the first capacitance portion 31d and the second extension 31b.

As illustrated in FIG. 14B, the multilayer ceramic capacitor 1a may include the right-triangular fifth inspection electrode 57c continuous with the intersection between the first capacitance portion 31d and the first extension 31a and adjacent to the fifth dummy electrode 32c, the right-triangular seventh inspection electrode 57d continuous with the intersection between the first capacitance portion 31d and the second extension 31b and adjacent to the sixth dummy electrode 32d, a right-triangular ninth inspection electrode 59a continuous with the intersection between the first capacitance portion 31d and the fifth extension 31e and adjacent to the fifth dummy electrode 32c, and a right-triangular tenth inspection electrode 59b continuous with the intersection between the first capacitance portion 31d and the sixth extension 31f and adjacent to the sixth dummy electrode 32d.

As illustrated in FIG. 14C, the multilayer ceramic capacitor 1a may include the right-triangular fifth inspection electrode 57c continuous with the intersection between the first capacitance portion 31d and the first extension 31a and adjacent to the fifth dummy electrode 32c, the right-triangular seventh inspection electrode 57d continuous with the intersection between the first capacitance portion 31d and the second extension 31b and adjacent to the sixth dummy electrode 32d, a right-triangular eleventh inspection electrode 60a continuous with the intersection between the first capacitance portion 31d and the fifth extension 31e and adjacent to the first dummy extension 32a, and a right-triangular twelfth inspection electrode 60b continuous with the intersection between the first capacitance portion 31d and the sixth extension 31f and adjacent to the second dummy extension 32b.

As illustrated in FIG. 14D, the multilayer ceramic capacitor 1a may include the right-triangular fifth inspection electrode 57c continuous with the intersection between the first capacitance portion 31d and the first extension 31a and adjacent to the fifth dummy electrode 32c, the right-triangular seventh inspection electrode 57d continuous with the intersection between the first capacitance portion 31d and the second extension 31b and adjacent to the sixth dummy electrode 32d, the right-triangular ninth inspection electrode 59a continuous with the first capacitance portion 31d and the fifth extension 31e and adjacent to the fifth dummy electrode 32c, the right-triangular tenth inspection electrode 59b continuous with the intersection between the first capacitance portion 31d and the sixth extension 31f and adjacent to the sixth dummy electrode 32d, the right-triangular eleventh inspection electrode 60a continuous with the intersection between the first capacitance portion 31d and the fifth extension 31e and adjacent to the first dummy extension 32a, and the right-triangular twelfth inspection electrode 60b continuous with the intersection between the first capacitance portion 31d and the sixth extension 31f and adjacent to the second dummy extension 32b.

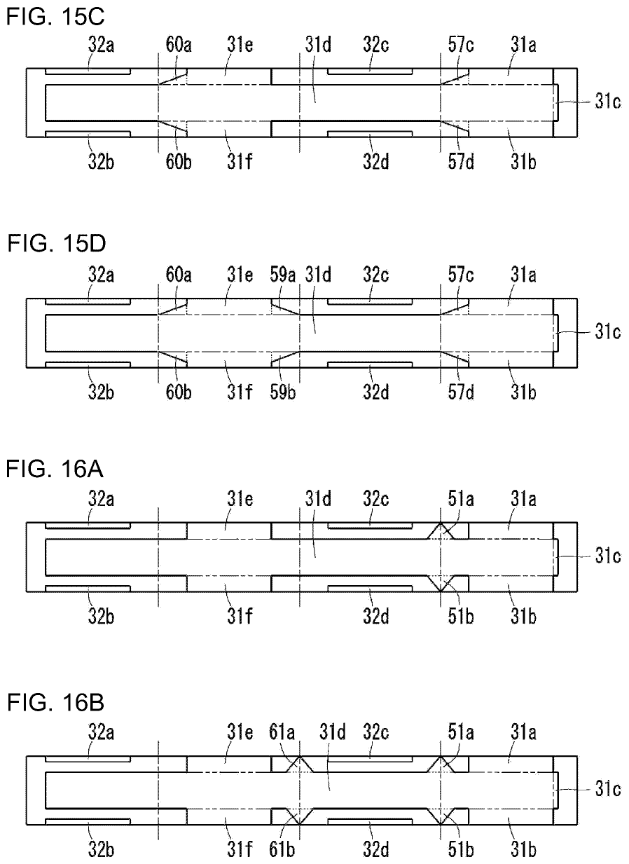

FIGS. 15A to 15D are diagrams of other electrode patterns on the multilayer ceramic capacitor 1a according to the embodiment illustrated in FIGS. 12 and 13. As illustrated in FIG. 15A, the multilayer ceramic capacitor 1a may include the right-triangular fifth inspection electrode 57c continuous with the intersection between the first capacitance portion 31d and the first extension 31a, adjacent to the fifth dummy electrode 32c, and located inward from the first surface 2a, and the right-triangular seventh inspection electrode 57d continuous with the intersection between the first capacitance portion 31d and the second extension 31b, adjacent to the sixth dummy electrode 32d, and located inward from the second surface 2b.

As illustrated in FIG. 15B, the multilayer ceramic capacitor 1a may include the right-triangular fifth inspection electrode 57c continuous with the intersection between the first capacitance portion 31d and the first extension 31a, adjacent to the fifth dummy electrode 32c, and located inward from the first surface 2a, the right-triangular seventh inspection electrode 57d continuous with the intersection between the first capacitance portion 31d and the second extension 31b, adjacent to the sixth dummy electrode 32d, and located inward from the second surface 2b, the right-triangular ninth inspection electrode 59a continuous with the intersection between the first capacitance portion 31d and the fifth extension 31e, adjacent to the fifth dummy electrode 32c, and located inward from the first surface 2a, and the right-triangular tenth inspection electrode 59b continuous with the intersection between the first capacitance portion 31d and the sixth extension 31f, adjacent to the sixth dummy electrode 32d, and located inward from the second surface 2b.

As illustrated in FIG. 15C, the multilayer ceramic capacitor 1a may include the right-triangular fifth inspection electrode 57c continuous with the intersection between the first capacitance portion 31d and the first extension 31a, adjacent to the fifth dummy electrode 32c, and located inward from the first surface 2a, the right-triangular seventh inspection electrode 57d continuous with the intersection between the first capacitance portion 31d and the second extension 31b, adjacent to the sixth dummy electrode 32d, and located inward from the second surface 2b, the right-triangular eleventh inspection electrode 60a continuous with the intersection between the first capacitance portion 31d and the fifth extension 31e, adjacent to the first dummy extension 32a, and located inward from the first surface 2a, and the right-triangular twelfth inspection electrode 60b continuous with the intersection between the first capacitance portion 31d and the sixth extension 31f, adjacent to the second dummy extension 32b, and located inward from the second surface 2b.

As illustrated in FIG. 15D, the multilayer ceramic capacitor 1a may include the right-triangular fifth inspection electrode 57c continuous with the intersection between the first capacitance portion 31d and the first extension 31a, adjacent to the fifth dummy electrode 32c, and located inward from the first surface 2a, the right-triangular seventh inspection electrode 57d continuous with the intersection between the first capacitance portion 31d and the second extension 31b, adjacent to the sixth dummy electrode 32d, and located inward from the second surface 2b, the right-triangular ninth inspection electrode 59a continuous with the first capacitance portion 31d and the fifth extension 31e, adjacent to the fifth dummy electrode 32c, and located inward from the first surface 2a, the right-triangular tenth inspection electrode 59b continuous with the intersection between the first capacitance portion 31d and the sixth extension 31f, adjacent to the sixth dummy electrode 32d, and located inward from the second surface 2b, the right-triangular eleventh inspection electrode 60a continuous with the intersection between the first capacitance portion 31d and the fifth extension 31e, adjacent to the first dummy extension 32a, and located inward from the first surface 2a, and the right-triangular twelfth inspection electrode 60b continuous with the intersection between the first capacitance portion 31d and the sixth extension 31f, adjacent to the second dummy extension 32b, and located inward from the second surface 2b.

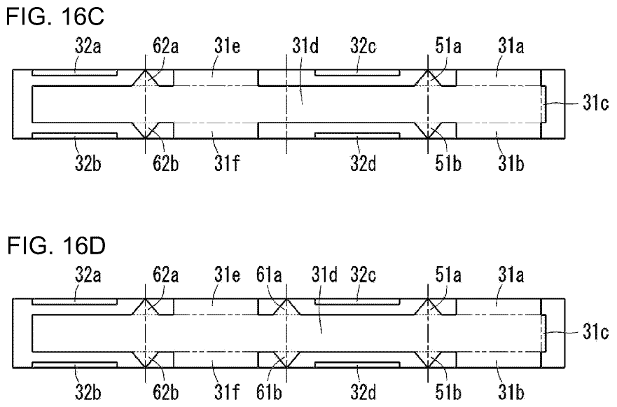

FIGS. 16A to 16D are diagrams of other electrode patterns on the multilayer ceramic capacitor 1a according to the embodiment illustrated in FIGS. 12 and 13. As illustrated in FIG. 16A, the multilayer ceramic capacitor 1a may include the triangular first inspection electrode 51a continuous with a portion of the first capacitance portion 31d between the first extension 31a and the fifth dummy electrode 32c and the triangular second inspection electrode 51b continuous with a portion of the first capacitance portion 31d between the second extension 31b and the sixth dummy electrode 32d.

As illustrated in FIG. 16B, the multilayer ceramic capacitor 1a may include the triangular first inspection electrode 51a continuous with the portion of the first capacitance portion 31d between the first extension 31a and the fifth dummy electrode 32c, the triangular second inspection electrode 51b continuous with the portion of the first capacitance portion 31d between the second extension 31b and the sixth dummy electrode 32d, a triangular thirteenth inspection electrode 61a continuous with a portion of the first capacitance portion 31d between the fifth extension 31e and the fifth dummy electrode 32c, and a triangular fourteenth inspection electrode 61b continuous with a portion of the first capacitance portion 31d between the first extension 31a and the sixth dummy electrode 32d.

As illustrated in FIG. 16C, the multilayer ceramic capacitor 1a may include the triangular first inspection electrode 51 a continuous with the portion of the first capacitance portion 31d between the first extension 31a and the fifth dummy electrode 32c, the triangular second inspection electrode 51b continuous with the portion of the first capacitance portion 31d between the second extension 31b and the sixth dummy electrode 32d, a triangular fifteenth inspection electrode 62a continuous with a portion of the first capacitance portion 31d between the fifth extension 31e and the first dummy extension 32a, and a triangular sixteenth inspection electrode 62b continuous with a portion of the first capacitance portion 31d between the sixth extension 31f and the second dummy extension 32b.

As illustrated in FIG. 16D, the multilayer ceramic capacitor 1a may include the triangular first inspection electrode 51 a continuous with the portion of the first capacitance portion 31d between the first extension 31a and the fifth dummy electrode 32c, the triangular second inspection electrode 51b continuous with the portion of the first capacitance portion 31d between the second extension 31b and the sixth dummy electrode 32d, the triangular thirteenth inspection electrode 61a continuous with the portion of the first capacitance portion 31d between the fifth extension 31e and the fifth dummy electrode 32c, the triangular fourteenth inspection electrode 61b continuous with the portion of the first capacitance portion 31d between the first extension 31a and the sixth dummy electrode 32d, the triangular fifteenth inspection electrode 62a continuous with the portion of the first capacitance portion 31d between the fifth extension 31e and the first dummy extension 32a, and the triangular sixteenth inspection electrode 62b continuous with the portion of the first capacitance portion 31d between the sixth extension 31f and the second dummy extension 32b.

As described with reference to FIGS. 6A to 6C, the expansion rate M may be selected in the range of 0≤M≤36% based on the relationship between the total area S0, the expansion rate M of S, and the warpage D. The total area S0 is the total area of the first extension 31a, the second extension 31b, the first inspection electrode 51a, and the second inspection electrode 51b taken along section lines A-A, B-B, and C-C. This allows determination as to whether the fired multilayer ceramic capacitor 1 is acceptable or defective. This simple and thinner structure can minimize warpage without lowering mountability, thus increasing production efficiency.

In one or more embodiments of the present disclosure, the multilayer ceramic capacitor with a simple and thinner structure can minimize warpage without lowering mountability.

In one or more embodiments of the present disclosure, the mounting structure includes the multilayer ceramic capacitor described above, and is thus highly reliable.

In one or more embodiments of the present disclosure, the multilayer ceramic capacitor may be implemented in forms 1 to 5 described below.
(1) A multilayer ceramic capacitor, comprising:
   a body being a substantially rectangular prism, the body including a first internal electrode and a second internal electrode alternately stacked in a first direction with a dielectric layer between the first internal electrode and the second internal electrode, the body including a first electrode and a second electrode alternately stacked in the first direction with the dielectric layer between the first electrode and the second electrode, the body including a first side surface and a second side surface opposite to each other in the first direction, a first surface and a second surface opposite to each other, and a first end face and a second end face opposite to each other;
   a first external electrode and a second external electrode on the first surface; and
   a third external electrode and a fourth external electrode on the second surface,
   wherein the first internal electrode includes a first portion including a first capacitance portion, a first extension, and a second extension,
   the second internal electrode includes a second portion including a second capacitance portion, a third extension, and a fourth extension,
   the first electrode includes a first inspection electrode and a second inspection electrode,
   the second electrode includes a third inspection electrode and a fourth inspection electrode,
   the first extension extends to the first surface and is connected to the first external electrode, and the second extension extends to the second surface and is connected to the third external electrode, and
   the third extension extends to the first surface and is connected to the second external electrode, and the fourth extension extends to the second surface and is connected to the fourth external electrode.
(2) The multilayer ceramic capacitor according to (1), wherein
   the first inspection electrode includes at least one side connected to an intersection between the first capacitance portion and the first extension,
   the second inspection electrode includes at least one side connected to an intersection between the first capacitance portion and the second extension,
   the third inspection electrode includes at least one side connected to an intersection between the second capacitance portion and the third extension, and
   the fourth inspection electrode includes at least one side connected to an intersection between the second capacitance portion and the fourth extension.
(3) The multilayer ceramic capacitor according to (1) or (2), wherein
   the first internal electrode further includes a first dummy portion electrically isolated from the first portion,
   the second internal electrode further includes a second dummy portion electrically isolated from the second portion,
   the first dummy portion includes a first dummy extension extending to the first surface and a second dummy extension extending to the second surface,
   the second dummy portion includes a third dummy extension extending to the first surface and a fourth dummy extension extending to the second surface,
   the first dummy extension is connected to the second external electrode, and the second dummy extension is connected to the fourth external electrode, and
   the third dummy extension is connected to the first external electrode, and the fourth dummy extension is connected to the third external electrode.
(4) The multilayer ceramic capacitor according to any one of (1) to (3), wherein
   an expansion proportion M based on M={(S/S0)−1}×100 is within 0≤M≤36% when a warpage D is less than or equal to 10%, where the warpage D is T1/T2, T1 is a thickness of the body before firing, T2 is a distance between two parallel planes in contact with opposite ends of the body after firing in a thickness direction and parallel to a thickness direction of the two parallel planes, S is a measured area of a portion of the first extension exposed on the first surface after firing, S0 is a design area of the portion of the first extension exposed on the first surface, and M is an expansion proportion of the portion of the first extension exposed on the first surface resulting from firing.
(5) The multilayer ceramic capacitor according to any one of (1) to (4), wherein
   the dielectric layer is rectangular,
   the first surface and the second surface are perpendicular to the first direction and opposite to each other in a second direction parallel to a width direction of the dielectric layer, and
   the first end face and the second end face are opposite to each other in a third direction perpendicular to the first direction and the second direction and parallel to a length direction of the dielectric layer.

In one or more embodiments of the present disclosure, the multilayer ceramic capacitor mounting structure may be implemented in form 6 described below.
(6) A multilayer ceramic capacitor mounting structure, comprising:
   the multilayer ceramic capacitor according to any one of (1) to (5); and
   a substrate including a mounting surface,
   wherein the multilayer ceramic capacitor is mounted on the mounting surface with the first side surface perpendicular to the mounting surface.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### REFERENCE SIGNS

1, la multilayer ceramic capacitor
2 body
2a first surface
2b second surface
2c first side surface
2d second side surface
2e first end face
2f second end face
3 first internal electrode
4 second internal electrode
5 dielectric layer
7, 8 external electrode
7a first external electrode
7b third external electrode
8a second external electrode
8b fourth external electrode
31 first portion
31a first extension
31b second extension
31d first capacitance portion
32 first dummy portion
32a first dummy extension
32b second dummy extension
41 second portion
41a third extension
41b fourth extension
41d second capacitance portion
7a first external electrode
8a second external electrode
42a third dummy extension
42b fourth dummy extension
51a first inspection electrode
51b second inspection electrode
52a third inspection electrode
52b fourth inspection electrode
57c fifth inspection electrode
56a sixth inspection electrode
57d seventh inspection electrode
56b eighth inspection electrode
59a ninth inspection electrode
59b tenth inspection electrode
60a eleventh inspection electrode
60b twelfth inspection electrode
61a thirteenth inspection electrode
61b fourteenth inspection electrode
62a fifteenth inspection electrode
62b sixteenth inspection electrode
100 mounting structure

1. A multilayer ceramic capacitor, comprising:
a body including a first internal electrode and a second internal electrode alternately stacked in a first direction with a dielectric layer sandwiched by the first internal electrode and the second internal electrode, the body including a first electrode and a second electrode alternately stacked in the first direction with the dielectric layer sandwiched by the first electrode and the second electrode, the body including a first side surface and a second side surface opposite to each other in the first direction, a first surface and a second surface opposite to each other, and a first end face and a second end face opposite to each other;
a first external electrode and a second external electrode on the first surface; and
a third external electrode and a fourth external electrode on the second surface,
wherein the first internal electrode includes a first portion, the first portion includes a first capacitance portion, a first extension, and a second extension,
the second internal electrode includes a second portion, the second portion includes a second capacitance portion, a third extension, and a fourth extension,
the first electrode includes a first inspection electrode and a second inspection electrode, the first inspection electrode is located between the first capacitance portion and the first surface, the second inspection electrode is located between the first capacitance portion and the second surface,
the second electrode includes a third inspection electrode and a fourth inspection electrode,
the first extension is extended to the first surface and is connected to the first external electrode, and the second extension is extended to the second surface and is connected to the third external electrode, and
the third extension is extended to the first surface and is connected to the second external electrode, and the fourth extension is extended to the second surface and is connected to the fourth external electrode.

2. The multilayer ceramic capacitor according to claim 1, wherein
the first inspection electrode is connected to at least one of the first capacitance portion and the first extension,
the second inspection electrode is connected to at least one of the first capacitance portion and the second extension,
the third inspection electrode is connected to at least one of the second capacitance portion and the third extension, and
the fourth inspection electrode is connected to at least one of the second capacitance portion and the fourth extension.

3. The multilayer ceramic capacitor according to claim 1, wherein
the first internal electrode further includes a first dummy portion electrically isolated from the first portion,
the second internal electrode further includes a second dummy portion electrically isolated from the second portion,
the first dummy portion includes a first dummy extension extending to the first surface and a second dummy extension extending to the second surface,
the second dummy portion includes a third dummy extension extending to the first surface and a fourth dummy extension extending to the second surface,
the first dummy extension is connected to the second external electrode, and the second dummy extension is connected to the fourth external electrode, and
the third dummy extension is connected to the first external electrode, and the fourth dummy extension is connected to the third external electrode.

4. The multilayer ceramic capacitor according to claim 1, wherein
an expansion proportion M based on M={(S/S0)−1}×100 is within 0≤M≤36% when a warpage D is less than or equal to 10%, where the warpage D is T1/T2, T1 is a thickness of the body before firing, T2 is a distance between two parallel planes in contact with opposite ends of the body after firing in a thickness direction and parallel to a thickness direction of the two parallel planes, S is a measured area of a portion of the first extension exposed on the first surface after firing, S0 is a design area of the portion of the first extension exposed on the first surface, and M is an expansion proportion of the portion of the first extension exposed on the first surface resulting from firing.

5. The multilayer ceramic capacitor according to claim 1, wherein
the dielectric layer is rectangular,
the first surface and the second surface are perpendicular to the first direction and opposite to each other in a second direction parallel to a width direction of the dielectric layer, and
the first end face and the second end face are opposite to each other in a third direction perpendicular to the first direction and the second direction and parallel to a length direction of the dielectric layer.

6. A multilayer ceramic capacitor mounting structure, comprising:
the multilayer ceramic capacitor according to claim 1; and
a substrate including a mounting surface,
wherein the multilayer ceramic capacitor is mounted on the mounting surface with the first side surface perpendicular to the mounting surface.

7. The multilayer ceramic capacitor according to claim 1,
wherein
the first inspection electrode is connected to the first capacitance portion and the first extension,
the second inspection electrode is connected to the first capacitance portion and the second extension,
the third inspection electrode is connected to the second capacitance portion and the third extension, and
the fourth inspection electrode is connected to the second capacitance portion and the fourth extension.
